(19) United States
(12) Patent Application Publication
(10) Pub. No.: US 2007/0264599 A1
(43) Pub. Date: Nov. 15, 2007

(54) Method for manufacturing semiconductor device using immersion lithography process with filtered air

(75) Inventors: Sung Koo Lee, Seoul (KR); Jae Chang Jung, Seoul (KR)

Correspondence Address: HELLER EHRMAN LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/647,230

(22) Filed: Dec. 29, 2006

(30) Foreign Application Priority Data
May 11, 2006 (KR) 10-2006-0042537

(51) Int. Cl. G03F 7/26

(52) U.S. Cl. 430/322; 430/327

(57) ABSTRACT

A method for manufacturing a semiconductor device using an immersion lithography process is disclosed. The semiconductor device is manufactured by filtering an air by using an amine removing chemical filter; and applying the filtered air onto a photoresist film formed on a semiconductor substrate (i) after washing the photoresist film with water and before an exposure process or (ii) after washing the photoresist film with water and before a post-baking process. These steps thereby effectively prevent water mark defects.

### CROSS-REFERENCES TO RELATED APPLICATIONS

The present application claims priority to Korean patent application number 10-2006-0042537, filed on May 11, 2006, which is incorporated by reference in its entirety.

### BACKGROUND OF THE INVENTION

The present invention relates to a method for manufacturing a semiconductor device using an immersion lithography process.

In order to manufacture semiconductor devices that have been smaller, patterns have also become smaller. Researches have been made to develop resist and exposers for obtaining fine patterns.

In exposers, although KrF (248 nm) or ArF (193 nm) as an exposure light source have been applied to exposure process, attempts have been made to use short wavelength light sources such as F₂ (157 nm) or EUV (13 nm) or to increase numerical apertures (NA).

However, when new light sources such as F₂ are applied, a new exposer is required, which results in increasing manufacturing costs. Also, the increase of numerical apertures degrades a focus depth width.

Recently, an immersion lithography process has been developed in order to solve these problems. While an existing exposure process utilizes air having a refractive index of 1.0 as a medium of exposure beams between substrates having a photoresist film and an exposure lens of an exposer, the immersion lithography process utilizes a solution such as H₂O or an organic solvent having a refractive index of more than 1.0 as a medium of exposure beams. As a result, although exposer lights having the same wavelength are used, the same effect is obtained as when a light source of a short wavelength is used or a lens having high numerical apertures is used, without degradation depth of focus.

The immersion lithography process improves the depth of focus. Moreover, finer patterns can be formed with a conventional exposure wavelength.

However, when the semiconductor substrate is moved into a track and an exposure during the immersion lithography process, water that remains over the semiconductor substrate causes water mark defects. FIG. 1 is a SEM photograph illustrating such water mark defects in an immersion lithography process. As a result, it is difficult to apply the immersion lithography process to an actual process.

Although various recipes such as adjustment of the rotating speed of the semiconductor substrate have been optimized in order to remove water mask, it requires much time in set-up and improvement effects are unsatisfactory. Furthermore, a method of dehydrating water while blowing a nitrogen gas has been used. However, the method requires additional equipment for supplying an nitrogen gas of high purity to cause extra cost and special management and not to shorten a process time.

### BRIEF SUMMARY OF THE INVENTION

Embodiments of the present invention are directed at a method for manufacturing a semiconductor device.

A method for manufacturing a semiconductor device using an immersion lithography process comprises filtering an air by using an amine removing chemical filter; and applying the filtered air onto a photoresist film formed on a semiconductor substrate (i) after washing the photoresist film with water and before exposure process or (ii) after washing the photoresist film with water and before post-baking process.

In one embodiment, the method comprises the steps of: forming a photoresist film over an underlying layer formed over a semiconductor substrate; performing an exposure process with an exposer for immersion lithography; filtering an air by using an amine removing chemical filter; applying the filtered air onto a photoresist film formed on a semiconductor substrate after washing the photoresist film with water; post-baking the resulting structure; and developing the resulting structure to form a pattern.

In another embodiment, the method comprises the steps of: forming a photoresist film over an underlying layer of a semiconductor substrate; filtering an air by using an amine removing chemical filter; applying the filtered air onto a photoresist film formed on a semiconductor substrate after washing the photoresist film with water; performing an exposure process with an exposure for immersion lithography; filtering an air by using an amine removing chemical filter; applying the filtered air onto a photoresist film formed on a semiconductor substrate after washing the photoresist film with water; post-baking the resulting structure; and developing the resulting structure to form a desired pattern.

In other words, after a photoresist film is formed over an underlying layer of a semiconductor substrate, the photoresist film is subjected to air in the purified atmosphere filtered through a chemical filter for removing amine after a “pre-soak process” for washing the photoresist film with water or after a “post-soak process” for washing the photoresist film with water after performing an exposure process with an exposer for immersion lithography.

The temperature of the air applied onto the photoresist film ranges from 60 to 70° C. The chemical filter adsorbs amine in the air.

The filtered air is supplied into a nozzle mounted toward the semiconductor substrate in angle of more than 0° and less than 90° against the surface of the semiconductor substrate.

The filtered-air-applying process is performed with rotating the semiconductor substrate.

### BRIEF DESCRIPTION OF THE DRAWINGS

FIG. 1 is a SEM photograph illustrating water mark defects in an immersion lithography process.

FIGS. 2a through 2f are diagrams illustrating a method for manufacturing a semiconductor device using an immersion lithography process according to a specific embodiment of the present invention.

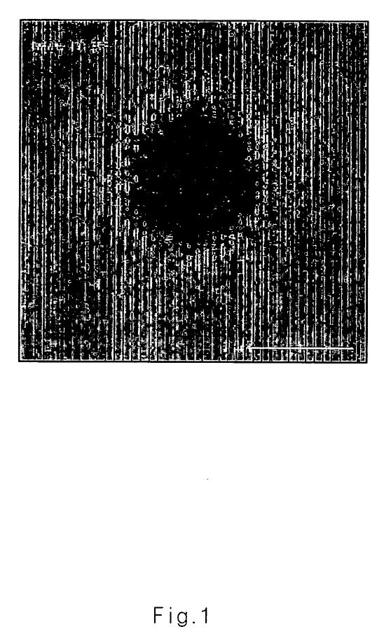

### DESCRIPTION OF SPECIFIC EMBODIMENTS

The present invention will be described in detail with reference to the accompanying drawings.

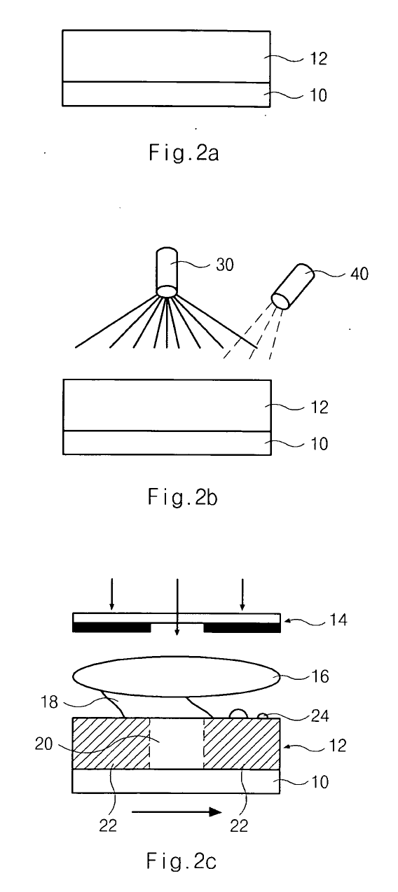

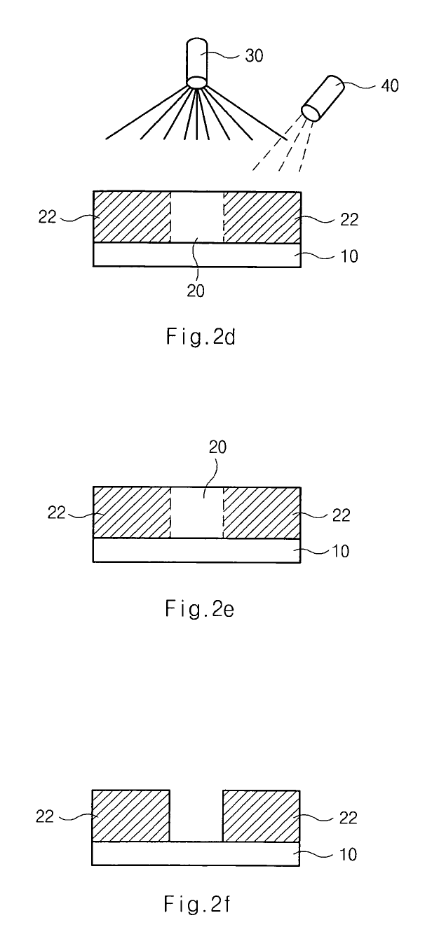

FIGS. 2a through 2f are diagrams illustrating a method for manufacturing a semiconductor device using an immersion lithography process according to a specific embodiment of the present invention.

A photoresist is coated over an underlying layer (not shown) of a semiconductor substrate 10, and soft-baked at about 130° C. for about 90 seconds to form a photoresist film 12 (Refer to FIG. 2a).

Deionized water is sprayed from a water sprayer 30 to wash the photoresist film 12. It is a pre-soak process for removing ingredients such as a photoacid generator or quencher that remain over the photoresist film 12 before exposure (Refer to FIG. 2b).

The pre-soak process reduces contamination of an exposure lens to improve exposure uniformity as well as pattern line-width uniformity. When the contamination of the exposure lens is reduced, the washing period of the lens is shortened so that the lens durability becomes longer as well as the exposer durability.

Air in the purified atmosphere filtered through a chemical filter for removing amine is blown off at the surface of the photoresist film 12 from a nozzle device 40 to dehydrate water that remains over the photoresist film 12. The temperature of the air applied onto the photoresist film 12 ranges from 60 to 70° C. to maximize dehydrating effects and shorten a dehydrating time. The nozzle device 40 is additionally mounted mounted toward the semiconductor substrate in angle of more than 0° and less than 90° against the surface of the semiconductor substrate. The semiconductor substrate 10 is rotated while accelerated to a relatively higher speed from between about 500 and about 1000 revolution per minute (rpm) to between about 2500 and about 6000 rpm.

Any of chemical filters for removing amine can be used which adsorb and remove amine impurities in the air.

An exposure process is performed with an exposure mask 14 and an exposer for immersion lithography. The light source of the exposure process is selected from the group consisting of G-line (436 nm), i-line (365 nm), KrF (248 nm), ArF (193 nm), F₂ (157 nm) and EUV (13 nm) (Refer to FIG. 2c).

H₂O is used as a medium of exposure beams between substrates of the semiconductor substrate 10 including the photoresist film 12 and the exposure lens 16 of the exposer. As a result of the exposure process, an exposed region 20 and an unexposed region 22 are formed in the photoresist film 12, and water drops 24 are formed over the photoresist film 12.

FIG. 2c shows that an exposure stage (not shown) is scanned and moved rightward. While the stopped stage is scanned, the water drop 24 is generated. When the stage is moved rightward, a meniscus of the H₂O 18 bends leftward and breaks to form water drops 24 which drops down to the photoresist film 12.

Deionized water is sprayed from the water sprayer 30 to perform a post-soak process for washing the photoresist film 12. Air in the purified atmosphere filtered through the chemical filter for removing amine is blown off at the surface of the photoresist film 12 from the nozzle device 40 to dehydrate water (Refer to FIG. 2d).

The temperature of the air applied onto the photoresist film 12 ranges from 60 to 70° C. to maximize dehydrating effects and shorten a dehydrating time. The nozzle device 40 is additionally mounted toward the semiconductor substrate in angle of more than 0° and less than 90° against the surface of the semiconductor substrate. The semiconductor substrate 10 is rotated while accelerated to a relatively higher speed from between about 500 and about 1000 revolution per minute (rpm) to between about 2500 and about 6000 rpm. In other words, the semiconductor substrate 10 is rotated while accelerated to a relatively higher speed during the blowing process.

As a result of the post-soak process, water marks generated by the water drops 24 are washed by the deionized water, which is rapidly dehydrated by the purified air so that there are no water marks over the photoresist film 12.

The resulting structure is baked at about 130° C. for about 90 seconds.

When the exposed region 20 is developed with 2.38 wt % TMAH aqueous solution for about 20 seconds or more, the unexposed region 22 remains as a resist pattern. As a result, defects such as T-top or bridges are not generated in the resist pattern.

As described above, according to an embodiment of the present invention, a photoresist film is washed with water before post-baking or before exposure using immersion lithography, and the photoresist film is subjected to air in the purified atmosphere filtered through a chemical filter for removing amine without requiring additional management such as raw material stock. Furthermore, the temperature of the air applied onto the photoresist film ranges from about 60 to about 70° C. to maximize dehydrating effects and shorten a dehydrating time, thereby effectively preventing water mark defects during the immersion lithography.

The above embodiments of the present invention are illustrative and not limitative. Various alternatives and equivalents are possible. Other additions, subtractions, or modifications are obvious in view of the present disclosure and are intended to fall within the scope of the appended claims.

What is claimed is:

1. A method for manufacturing a semiconductor device using an immersion lithography process, the method comprising the steps of: filtering an air by using an amine removing chemical filter; and applying the filtered air onto a photoresist film formed on a semiconductor substrate.

2. The method according to claim 1, wherein the filtered-air-applying process is performed after washing the photoresist film with water and before a post-baking process after exposure process.

3. The method according to claim 1, wherein the filtered-air-applying process is performed (i) after washing the photoresist film with water and before an exposure process; and (ii) after washing the photoresist film with water and before a post-baking process.

4. The method according to claim 1, wherein the filtered-air-applying process is performed after washing the photoresist film with water and before an exposure process.

5. The method according to claim 4, wherein the light source of the exposure process is selected from the group consisting of G-line (436 nm), i-line (365 nm), KrF (248 mm), ArF (193 nm), F₂ (157 nm) and EUV (13 nm).

6. The method according to claim 1, comprising the steps of:
forming a photoresist film over an underlying layer formed over a semiconductor substrate;
performing an exposure process with an exposer for immersion lithography;
filtering an air by using an amine removing chemical filter;
applying the filtered air onto a photoresist film formed on a semiconductor substrate after washing the photoresist film with water;
post-baking the resulting structure; and
developing the resulting structure to form a pattern.

7. The method according to claim 6, wherein the light source of the exposure process is selected from the group consisting of G-line (436 nm), i-line (365 nm), KrF (248 nm), ArF (193 nm), F₂ (157 nm) and EUV (13 nm).

8. The method according to claim 6, wherein H₂O is used as a medium of exposure beams between the semiconductor substrate including the photoresist film and an exposer lens of the exposer.

9. The method according to claim 6, wherein post-baking the resulting structure comprises baking the resulting structure at 130° C. for 90 seconds.

10. The method according to claim 6, wherein developing the resulting structure to form a pattern comprises developing an exposed region of the resulting structure with 2.38 wt % TMAH aqueous solution for 20 seconds or more when an unexposed region of the resulting structure remains as a photoresist pattern.

11. The method according to claim 1, comprising the steps of:
forming a photoresist film over an underlying layer of a semiconductor substrate;
filtering air by using an amine removing chemical filter;
applying the filtered air onto a photoresist film formed on a semiconductor substrate after washing the photoresist film with water;
performing an exposure process with an exposure for immersion lithography;
filtering an air by using an amine removing chemical filter;
applying the filtered air onto a photoresist film formed on a semiconductor substrate after washing the photoresist film with water;
post-baking the resulting structure; and
developing the resulting structure to form a desired pattern.

12. The method according to claim 11, wherein the light source of the exposure process is selected from the group consisting of G-line (436 nm), i-line (365 nm), KrF (248 nm), ArF (193 nm), F₂ (157 nm) and EUV (13 nm).

13. The method according to claim 11, wherein H₂O is used as a medium of exposure beams between the semiconductor substrate including the photoresist film and an exposer lens of the exposer.

14. The method according to claim 11, wherein post-baking the resulting structure comprises baking the resulting structure at 130° C. for 90 seconds.

15. The method according to claim 11, wherein developing the resulting structure to form a pattern comprises developing an exposed region of the resulting structure with 2.38 wt % TMAH aqueous solution for 20 seconds or more when an unexposed region of the resulting structure remains as a resist pattern.

16. The method according to claim 1, wherein the temperature of the air applied onto the photoresist film ranges from 60 to 70° C.

17. The method according to claim 1, wherein the chemical filter adsorbs amine in the air.

18. The method according to claim 1, wherein the filtered air is supplied into a nozzle mounted toward the semiconductor substrate in angle of more than 0° and less than 90° against the surface of the semiconductor substrate.

19. The method according to claim 1, wherein the filtered-air-applying process is performed with rotating the semiconductor substrate.

20. The method according to claim 17, wherein semiconductor substrate is rotated while accelerated to a relatively higher speed from between 500 and 1000 revolution per minute (rpm) to between 2500 and 6000 rpm.
